(19) United States
(12) Patent Application Publication
(10) Pub. No.: US 2011/0012302 A1
(43) Pub. Date: Jan. 20, 2011

(54) OFFICE MACHINE

(76) Inventor: Tsan-Yao Hung, Tainan County (TW)

Correspondence Address: NORTH AMERICA INTELLECTUAL PROPERTY CORPORATION, P.O. BOX 506, MERRIFIELD, VA, 22116, US

(21) Appl. No.: 12/831,198

(22) Filed: Jul. 6, 2010

(30) Foreign Application Priority Data
Jul. 17, 2009 (CN) 200910152196.5

(51) Int. Cl. B65H 5/06; H05K 5/03

(52) U.S. Cl. 271/277; 312/223.2

(57) ABSTRACT

An office machine includes a casing, a feeding-out mechanism and a first roller assembly. The feeding-out mechanism and the first roller assembly are disposed in the casing. The first roller assembly is used for feeding in a sheet member. The first roller assembly transports the sheet member to the feeding-out mechanism in a nipping manner. When the sheet member enters the feeding-out mechanism and then the feeding-out mechanism transports the sheet member, the first roller assembly does not nip the sheet member.

### BACKGROUND OF THE INVENTION

1. Field of the Invention

The invention relates to an office machine and, more particularly, to an office machine capable of preventing a sheet member from vibrating while the sheet member is being transported.

2. Description of the Prior Art

As technology advances, office machines (e.g. scanners, printers and so on) are getting more and more popular. Generally speaking, an office machine is equipped with feeding-in/out rollers for feeding in/out a sheet member. When a sheet member is being transported by an office machine, a recording module (such as image sensor, print head, etc.) of the office machine continuously executes preset function (such as scanning, printing, etc.) on the sheet member. There are drawbacks in conventional office machine listed as below. Vibration usually occurs when the sheet member is fed out of a feeding-in roller or fed in a feeding-out roller. At this time, since the recording module is executing preset function on the sheet member, the image quality of the sheet member will be affected by vibration, and kick noise is generated. When the sheet member is thicker, such as photo paper, the influence of vibration is more obvious.

### SUMMARY OF THE INVENTION

Therefore, an objective of the invention is to provide an office machine capable of selectively nipping or not nipping a sheet member while the sheet member is being transported, so as to effectively prevent the sheet member from vibrating. Thus, the aforesaid problems can be solved.

According to one embodiment, an office machine of the invention comprises a casing, a feeding-out mechanism and a first roller assembly. The feeding-out mechanism and the first roller assembly are disposed in the casing. The first roller assembly is used for feeding a sheet member in the casing. The first roller assembly transports the sheet member to the feeding-out mechanism in a nipping manner. When the sheet member enters the feeding-out mechanism and the feeding-out mechanism transports the sheet member, the first roller assembly does not nip the sheet member.

According to another embodiment, an office machine of the invention comprises a casing, a feeding-in mechanism and a first roller assembly. The feeding-in mechanism and the first roller assembly are disposed in the casing. The feeding-in mechanism is used for feeding a sheet member in the casing. The first roller assembly has a first roller and a second roller. A first predetermined distance is reserved between the first roller and the second roller. After a head end of the sheet member reaches a second predetermined distance from the first roller assembly, the first roller and the second roller start to nip and transport the sheet member.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a schematic diagram illustrating an office machine according to a first embodiment of the invention.

FIG. 2 is a schematic diagram illustrating the sheet member entering the second roller assembly in FIG. 1.

FIG. 3 is a schematic diagram illustrating an office machine according to a second embodiment of the invention.

FIG. 4 is a schematic diagram illustrating the sheet member pushing the second linkage assembly in FIG. 3.

FIG. 5 is a schematic diagram illustrating the sheet member further pushing the first linkage assembly in FIG. 4.

FIG. 6 is a schematic diagram illustrating an office machine according to a third embodiment of the invention.

FIG. 7 is a schematic diagram illustrating the sheet member entering the second roller assembly in FIG. 6.

### DETAILED DESCRIPTION

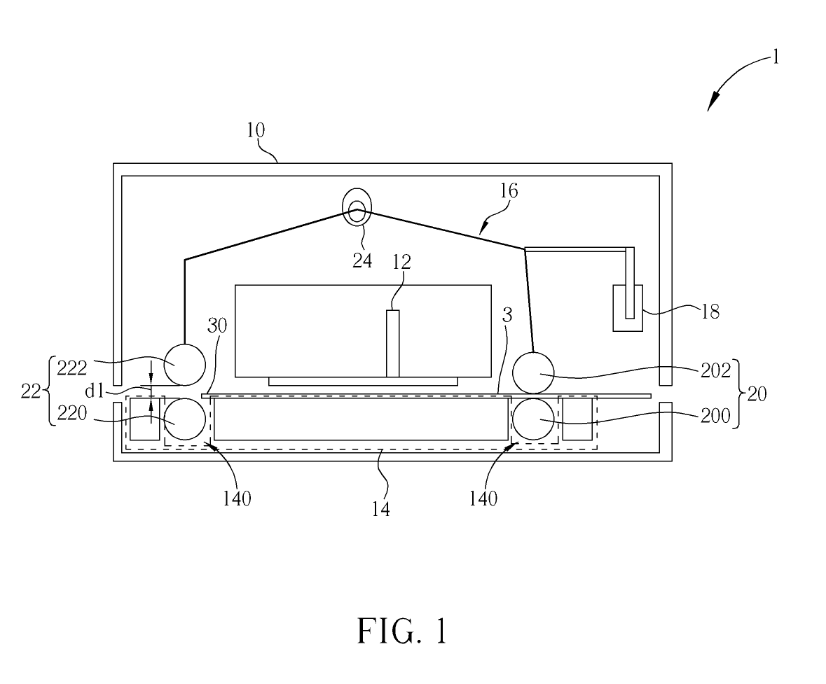

Referring to FIG. 1, FIG. 1 is a schematic diagram illustrating an office machine 1 according to a first embodiment of the invention. As shown in FIG. 1, the office machine 1 comprises a casing 10, a recording module 12, a supporting frame 14, a linkage assembly 16, an actuating device 18, a first roller assembly 20 and a second roller assembly 22. In this embodiment, the office machine 1 can be a scanner, and the recording module 12 can be an image sensor correspondingly. In another embodiment, the office machine 1 can be a printer, and the recording module 12 can be a print head correspondingly. Furthermore, the office machine 1 can be other devices equipped with feeding-in/out rollers and is not limited to scanner or printer.

The first roller assembly 20 may be used for feeding the sheet member 3 in the office machine 1, and the second roller assembly 22 may be used for feeding the sheet member 3 out of the office machine 1. At this time, the feeding-in mechanism of the invention may comprise the first roller assembly 20 and some essential components (not shown), such as driving motor, etc., for controlling the first roller assembly 20. The feeding-out mechanism may comprise the second roller assembly 22 and some essential components (not shown), such as driving motor, etc., for controlling the second roller assembly 22. In practical application, the sheet member 3 can be a photo paper or any paper for purposes of scanning, printing, etc.

By using the first roller assembly 20 as feeding-in roller assembly and using the second roller assembly 22 as feeding-out roller assembly, the operation of the invention is described in the following along with FIG. 1. As shown in FIG. 1, the recording module 12, the supporting frame 14, the linkage assembly 16, the actuating device 18, the first roller assembly 20 and the second roller assembly 22 are disposed in the casing 10. The first roller assembly 20 comprises a first roller 200 and a second roller 202, and the second roller assembly 22 comprises a third roller 220 and a fourth roller 222. The first roller 200 and the third roller 220 both are rotatably disposed in the casing 10. The second roller 202 and the fourth roller 222 are rotatably and movably connected to opposite ends of the linkage assembly 16 respectively. Besides, the linkage assembly 16 is pivotally connected to a pivoting shaft 24, and the actuating device 18 is connected to the linkage assembly 16. The actuating device 18 can be a driving motor and is used for actuating the linkage assembly 16 to drive the second roller 202 of the first roller assembly 20 and the fourth roller 222 of the second roller assembly 22 to move up and down. In this embodiment, the supporting frame 14 can support the sheet member 3 and provide the sheet member 3 a moving path. The supporting frame 14 has openings 140 for accommodating the first roller 200 and the third roller 220. It should be noticed that the invention is still enforceable without the supporting frame 14 since the first roller assembly 20 and the second roller assembly 22 can be disposed closely in small scanning devices.

When a user wants to use the office machine 1 to execute preset function (such as scanning, printing, etc.) on the sheet member 3, user needs to feed a head end 30 of the sheet member 3 in the first roller assembly 20. At this time, the rolling first roller assembly 20 transports the sheet member 3 to the second roller assembly 22 in a nipping manner, and the sheet member 3 moves along the supporting frame 14. Before the head end 30 of the sheet member 3 enters the second roller assembly 22, a first predetermined distance d1 is reserved between the third roller 220 and the fourth roller 222, as shown in FIG. 1.

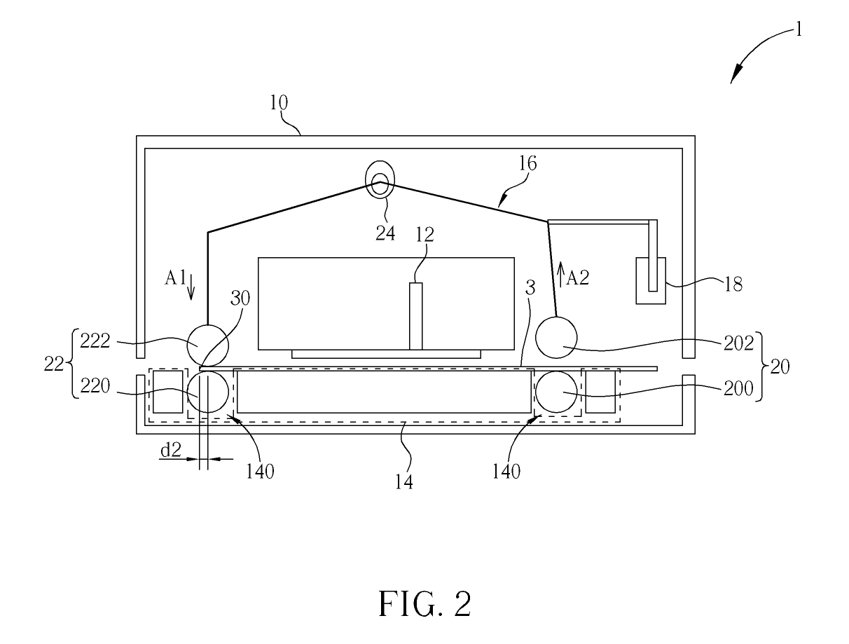

Referring to FIG. 2, FIG. 2 is a schematic diagram illustrating the sheet member 3 entering the second roller assembly 22 in FIG. 1. After the head end 30 of the sheet member 3 reaches a predetermined distance d2 from the second roller assembly 22, the actuating device 18 actuates the linkage assembly 16 to rotate with respect to the center of the pivoting shaft 24, and then the linkage assembly 16 drives the fourth roller 222 to move downward (i.e. the direction of arrow A1) and drives the second roller 202 to move upward (i.e. the direction of arrow A2). At this time, as shown in FIG. 2, the third roller 220 cooperates with the fourth roller 222 to nip and transport the sheet member 3, and the first roller 200 and the second roller 202 do not nip the sheet member 3 anymore.

In other words, when the head end 30 of the sheet member 3 enters the second roller assembly 22, since a predetermined distance d1 is reserved between the third roller 220 and the fourth roller 222, the head end 30 of the sheet member 3 can pass through the second roller assembly 22 smoothly. Similarly, after the sheet member 3 enters the second roller assembly 22, the first roller 200 and the second roller 202 do not nip the sheet member 3 anymore, such that the sheet member 3 can pass through the first roller assembly 20 smoothly. Accordingly, it can prevent the sheet member 3 from vibrating. When the recording module 12 executes preset function on the sheet member 3, good image quality can be obtained without kick noise.

It should be noticed that the invention may drive the second roller 202 to move upward after the head end 30 of the sheet member 30 enters the second roller assembly 22, or the invention may drive the second roller 202 move upward while the sheet member 3 is about to pass through the first roller assembly 20. In other words, the movement timing of the second roller 202 can be determined based on practical application. For example, if the size of the sheet member 3 is known, the invention may dispose a sensor (not shown) in front of the first roller assembly 20 to determine when the sheet member 3 is about to pass through the first roller assembly 20. Then, according to the size of the sheet member 3, the second roller 202 is driven to move upward and the fourth roller 222 is driven to move downward after the first roller assembly 20 rolls with a predetermined number of turns (such as ten turns). On the other hand, if the size of the sheet member 3 is unknown, the invention may dispose a sensor (not shown) in front of the second roller assembly 22 to determine when the sheet member 3 will enter the second roller assembly 22, and to make the second roller 202 move upward and the fourth roller 222 move downward after the sheet member 3 enters the second roller assembly 22.

In another embodiment, the invention may also dispose two actuating devices and two linkage assemblies (not shown), which are connected to the second roller 202 and the fourth roller 222 respectively, to drive the second roller 202 and the fourth roller 222 to move upward and downward correspondingly.

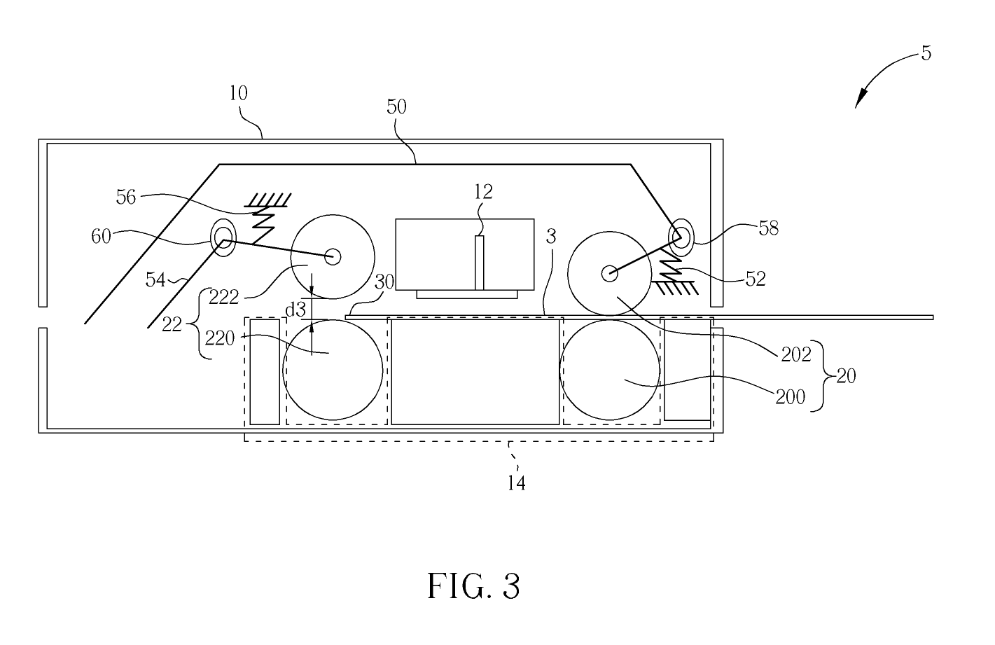

Referring to FIG. 3 to FIG. 5, the major difference between the office machine 5 and the aforesaid office machine 1 is that the office machine 5 utilizes a first linkage assembly 50, a first resilient member 52, a second linkage assembly 54 and a second resilient member 56 to drive the first roller assembly 20 and the second roller assembly 22 to nip or not to nip the sheet member 3, and all of them are disposed in the casing 10. It should be noticed that the structure and principle of the components with identical labels in FIGS. 1-3 and 5 are the same, so it will not be depicted herein. The first linkage assembly 50 is pivotally connected to a pivoting shaft 58, and the first resilient member 52 is connected to the first linkage assembly 50. The second roller 202 is rotatably and movably connected to the first linkage assembly 50. The second linkage assembly 54 is pivotally connected to a pivoting shaft 60, and the second resilient member 56 is connected to the second linkage assembly 54. The fourth roller 222 is rotatably and movably connected to the second linkage assembly 54.

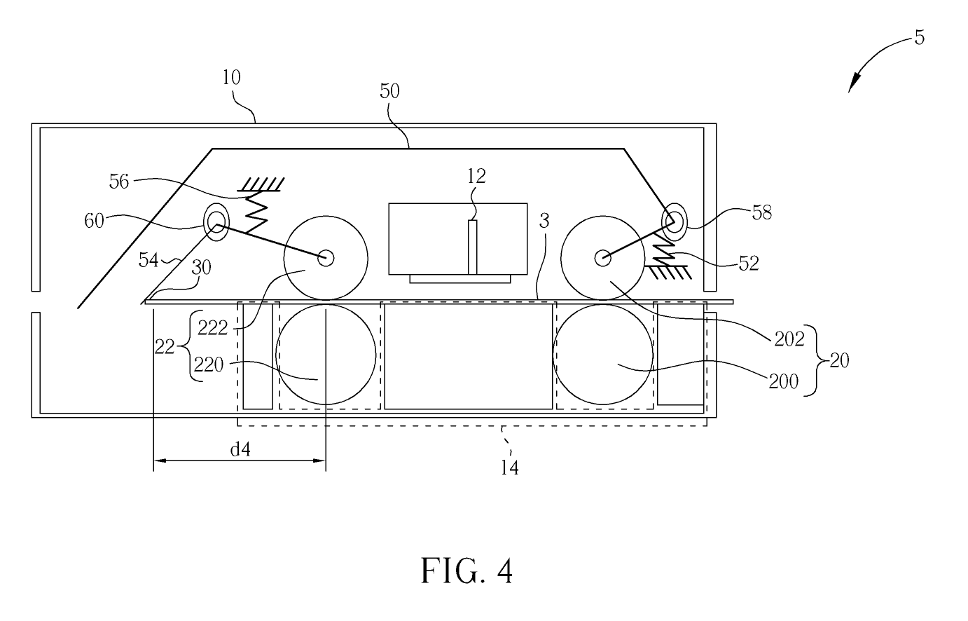

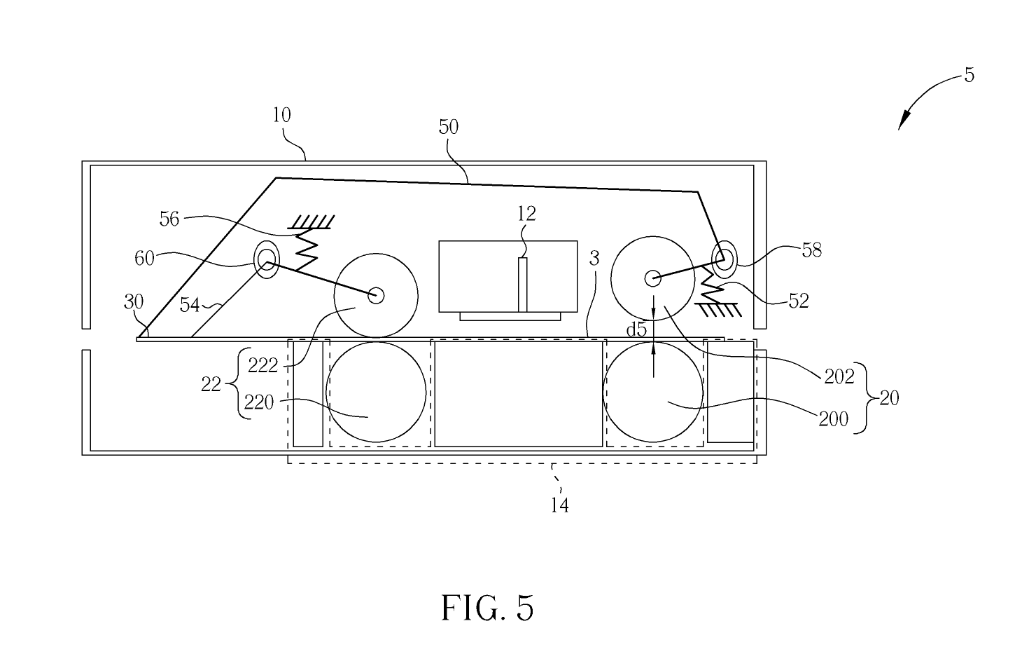

As shown in FIG. 3, the first roller assembly 20 transports the sheet member 3 to the second roller assembly 22 in a nipping manner. A predetermined distance d3 is reserved between the third roller 220 and the fourth roller 222 before the head end 30 of the sheet member 3 enters the second roller assembly 22. As shown in FIG. 4, after the head end 30 of the sheet member 3 reaches a predetermined distance d4 from the second roller assembly 22, the second linkage assembly 54 will be pushed by the head end 30 of the sheet member 3 to make the fourth roller 222 and the third roller 220 shorten the predetermined distance d3 to a nipping state, such that the second roller assembly 22 nips and transports the sheet member 3. At this time, the second resilient member 56 is stretched. Afterward, as shown in FIG. 5, the sheet member 3 moves forth and then pushes the first linkage assembly 50 to make the second roller 202 and the first roller 200 generate a predetermined distance d5, such that the first roller assembly 200 does not nip the sheet member 3 anymore. At this time, the first resilient member 52 is stretched. Accordingly, it can prevent the sheet member 3 from vibrating. In this embodiment, the sheet member 3 should have specific stiffness, such as a photo paper, for pushing the first linkage assembly 50 and the second linkage assembly 54 smoothly.

In this embodiment, after the sheet member 3 leaves the second linkage assembly 54, the stretched second resilient member 56 provides an elastic force to make the second roller assembly 22 regenerate the predetermined distance d3. Similarly, after the sheet member 3 leaves the first linkage assembly 50, the stretched first resilient member 52 provides an elastic force to make the first roller assembly 20 shorten the predetermined distance d5 to a nipping state.

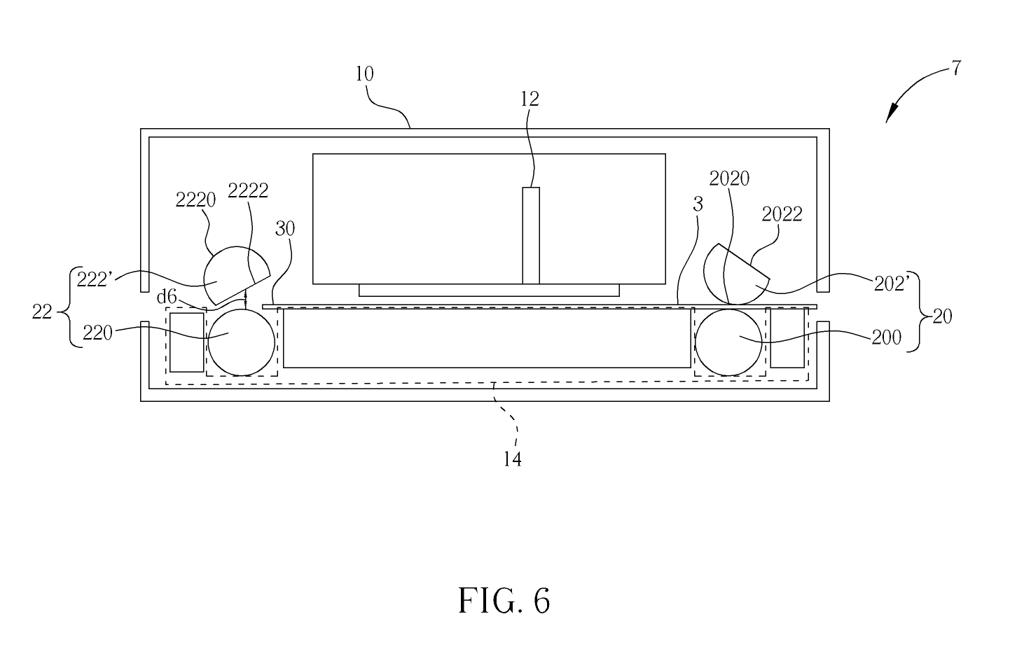

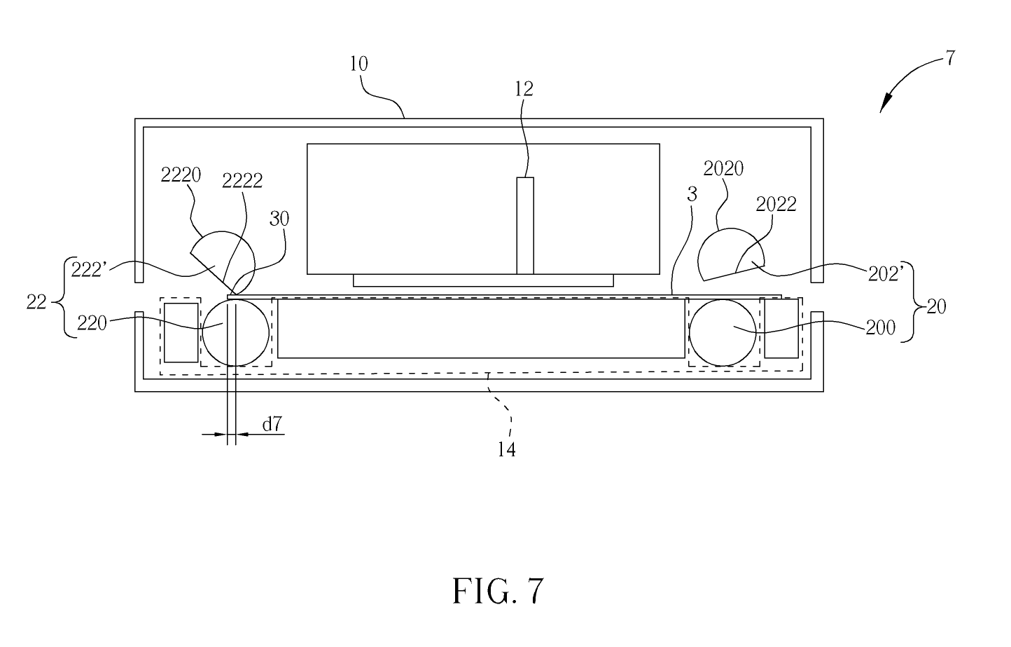

Referring to FIG. 6 and FIG. 7, the major difference between the office machine 7 and the aforesaid office machine 1 is that the office machine 7 utilizes a second roller 202′ and a fourth roller 222′ with specific structural design to cooperate with the first roller 200 and the third roller 220 to nip or not to nip the sheet member 3 selectively. It should be noticed that the structure and principle of the components with identical labels in FIGS. 1, 6 and 7 are the same, so it will not be depicted herein. As shown in FIG. 6, the first roller 200, the second roller 202′, the third roller 220 and the fourth roller 222′ are rotatably disposed in the casing 10. The second roller 202′ has a contact portion 2020 and a non-contact portion 2022, wherein the contact portion 2020 cooperates with the first roller 200 to nip the sheet member 3, and the non-contact portion 2022 cooperates with the first roller 200 not to nip the sheet member 3. Besides, the fourth roller 222′ also has a contact portion 2220 and a non-contact portion 2222, wherein the contact portion 2220 cooperates with the third roller 220 to nip the sheet member 3, and the non-contact portion 2222 cooperates with the third roller 220 not to nip the sheet member 3.

As shown in FIG. 6, the first roller assembly 20 transports the sheet member 3 to the second roller assembly 22 in a nipping manner. Before the head end 30 of the sheet member 3 enters the second roller assembly 22, a predetermined distance d6 is reserved between the third roller 220 and the non-contact portion 2222 of the fourth roller 222′. As shown in FIG. 7, after the head end 30 of the sheet member 3 reaches a predetermined distance d7 from the second roller assembly 22, the contact portion 2220 of the fourth roller 222′ cooperates with the third roller 220 to nip the sheet member 3, such that the second roller assembly 22 nips and transports the sheet member 3. At this time, the non-contact portion 2022 of the second roller 202′ cooperates with the first roller 200 not to nip the sheet member 3. Accordingly, the sheet member 3 can pass smoothly without vibration when entering the second roller assembly 22 and leaving the first roller assembly 20.

Compared to the prior art, the feeding-in mechanism (such as the aforesaid first roller assembly) or the feeding-out mechanism (such as the aforesaid second roller assembly) of the office machine of the invention can selectively nip or not nip the sheet member, so as to effectively prevent the sheet member from vibrating while the sheet member is being transported. Therefore, no matter when the sheet member leaves the feeding-in roller or enters the feeding-out roller, the recording module can execute preset function on the sheet member well, and good image quality can be obtained without kick noise.

Those skilled in the art will readily observe that numerous modifications and alterations of the device and method may be made while retaining the teachings of the invention.

What is claimed is:

1. An office machine for transporting a sheet member, the office machine comprising:
a casing;
a feeding-out mechanism disposed in the casing; and
a first roller assembly, disposed in the casing, for feeding the sheet member in the casing, the first roller assembly transporting the sheet member to the feeding-out mechanism in a nipping manner, when the sheet member enters the feeding-out mechanism and the feeding-out mechanism transports the sheet member, the first roller assembly not nipping the sheet member.

2. The office machine of claim 1, wherein the feeding-out mechanism comprises a second roller assembly disposed in the casing, the second roller assembly having a third roller and a fourth roller, a first predetermined distance is reserved between the third roller and the fourth roller, after ahead end of the sheet member reaches a second predetermined distance from the second roller assembly, the third roller and the fourth roller starts to nip and transport the sheet member.

3. The office machine of claim 2 further comprising:
a linkage assembly disposed in the casing and connected to the first roller assembly and the second roller assembly; and
an actuating device, disposed in the casing and connected to the linkage assembly, for actuating the linkage assembly driving the first roller assembly and the second roller assembly to nip or not to nip the sheet member selectively.

4. The office machine of claim 3, wherein the first roller assembly comprises:
a first roller rotatably disposed in the casing; and
a second roller rotatably and movably connected to the linkage assembly, the linkage assembly being capable of driving the second roller to nip or not to nip the sheet member.

5. The office machine of claim 1, wherein the first roller assembly comprises a first roller and a second roller, the office machine further comprising:
a first linkage assembly disposed in the casing, the second roller being rotatably and movably connected to the first linkage assembly, the first linkage assembly being pushed by a head end of the sheet member to generate a third predetermined distance between the second roller and the first roller; and
a first resilient member disposed in the casing and connected to the first linkage assembly, after the sheet member leaves the first linkage assembly, the first resilient member providing an elastic force to make the first roller assembly shorten the third predetermined distance to a nipping state.

6. The office machine of claim 2 further comprising:
a second linkage assembly disposed in the casing, the fourth roller being rotatably and movably connected to the second linkage assembly, the second linkage assembly being pushed by the head end of the sheet member to make the fourth roller and the third roller shorten the first predetermined distance to a nipping state; and
a second resilient member disposed in the casing and connected to the second linkage assembly, after the sheet member leaves the second linkage assembly, the second resilient member providing an elastic force to make the second roller assembly generate the first predetermined distance.

7. The office machine of claim 1, wherein the first roller assembly comprises:
a first roller rotatably disposed in the casing; and
a second roller rotatably disposed in the casing, the second roller having a contact portion and a non-contact portion, the contact portion of the second roller cooperating with the first roller to nip the sheet member, the non-contact portion of the second roller cooperating with the first roller not to nip the sheet member.

8. The office machine of claim 2, wherein the fourth roller has a contact portion and a non-contact portion, the contact portion of the fourth roller cooperates with the third roller to nip the sheet member, and the non-contact portion of the fourth roller cooperates with the third roller not to nip the sheet member.

9. An office machine for transporting a sheet member, the office machine comprising:
a casing;
a feeding-in mechanism, disposed in the casing, for feeding the sheet member in the casing; and
a first roller assembly disposed in the casing, the first roller assembly having a first roller and a second roller, a first predetermined distance being reserved between the first roller and the second roller, after a head end of the sheet member reaches a second predetermined distance from the first roller assembly, the first roller and the second roller start to nip and transport the sheet member.

10. The office machine of claim 9, wherein the feeding-in mechanism comprises a second roller assembly disposed in the casing and used for feeding the sheet member in the casing, the second roller assembly transports the sheet member to the first roller assembly in a nipping manner, after the head end of the sheet member enters the first roller assembly and the first roller assembly transports the sheet member, the second roller assembly does not nip the sheet member.

11. The office machine of claim 10 further comprising:
a linkage assembly disposed in the casing and connected to the first roller assembly and the second roller assembly; and
an actuating device, disposed in the casing and connected to the linkage assembly, for actuating the linkage assembly driving the first roller assembly and the second roller assembly to nip or not to nip the sheet member selectively.

12. The office machine of claim 11, wherein the second roller is rotatably and movably connected to the linkage assembly, the linkage assembly is capable of driving the second roller to nip or not to nip the sheet member.

13. The office machine of claim 11, wherein the second roller assembly comprises:
a third roller rotatably disposed in the casing; and
a fourth roller rotatably and movably connected to the linkage assembly, the linkage assembly being capable of driving the fourth roller to nip or not to nip the sheet member.

14. The office machine of claim 9 further comprising:
a first linkage assembly disposed in the casing, the second roller being rotatably and movably connected to the first linkage assembly, the first linkage assembly being pushed by the head end of the sheet member to make the second roller and the first roller shorten the first predetermined distance to a nipping state; and
a first resilient member disposed in the casing and connected to the first linkage assembly, after the sheet member leaves the first linkage assembly, the first resilient member providing an elastic force to make the first roller assembly generate the first predetermined distance.

15. The office machine of claim 10, wherein the second roller assembly comprises a third roller and a fourth roller, the office machine further comprising:
a second linkage assembly disposed in the casing, the fourth roller being rotatably and movably connected to the second linkage assembly, the second linkage assembly being pushed by the head end of the sheet member to generate a third predetermined distance between the fourth roller and the third roller; and
a second resilient member disposed in the casing and connected to the second linkage assembly, after the sheet member leaves the second linkage assembly, the second resilient member providing an elastic force to make the second roller assembly shorten the third predetermined distance to a nipping state.

16. The office machine of claim 9, wherein the second roller has a contact portion and a non-contact portion, the contact portion of the second roller cooperates with the first roller to nip the sheet member, and the non-contact portion of the second roller cooperates with the first roller not to nip the sheet member.

17. The office machine of claim 10, wherein the second roller assembly comprises:
a third roller rotatably disposed in the casing; and
a fourth roller rotatably disposed in the casing, the fourth roller having a contact portion and a non-contact portion, the contact portion of the fourth roller cooperating with the third roller to nip the sheet member, the non-contact portion of the fourth roller cooperating with the third roller not to nip the sheet member.
